(19) United States
(12) Patent Application Publication
(10) Pub. No.: US 2025/0293065 A1
(43) Pub. Date: Sep. 18, 2025

(54) BONDING APPARATUS AND BONDING METHOD

(71) Applicant: Tokyo Electron Limited, Tokyo (JP)

(72) Inventors: Takuro MASUZUMI, Koshi City (JP); Norifumi KOHAMA, Koshi City (JP); Hayato TANOUE, Koshi City (JP); Yosuke OMORI, Koshi City (JP); Norio WADA, Koshi City (JP); Kimio MOTODA, Koshi City (JP)

(73) Assignee: Tokyo Electron Limited, Tokyo (JP)

(21) Appl. No.: 19/079,911

(22) Filed: Mar. 14, 2025

(30) Foreign Application Priority Data
Mar. 15, 2024 (JP) 2024-040849

(51) Int. Cl. H01L 21/677; H01L 21/66; H01L 21/683

(52) U.S. Cl. CPC H01L 21/67709; H01L 21/6838; H01L 22/12

(57) ABSTRACT

A bonding apparatus includes a first holder, a pushing member and a controller. The first holder holds a first substrate from below. The second holder is disposed above the first holder and holds a second substrate from above. The pushing member pushes down a central portion of the second substrate. The first holder includes an outer attraction structure, an inner attraction structure and a transforming mechanism. The outer attraction structure attracts a peripheral portion of the first substrate. The inner attraction structure attracts a portion of the first substrate inside the peripheral portion. The transforming mechanism transforms the outer attraction structure relative to the inner attraction structure. The controller acquires information of a height of the peripheral portion from a reference surface and controls the transforming mechanism based on the acquired information.

### CROSS-REFERENCE TO RELATED APPLICATION

This application claims the benefit of Japanese Patent Application No. 2024-040849 filed on Mar. 15, 2024, the entire disclosures of which are incorporated herein by reference.

### TECHNICAL FIELD

The exemplary embodiments described herein pertain generally to a bonding apparatus and a bonding method.

### BACKGROUND

Conventionally, there is known a bonding apparatus configured to bond substrates, such as semiconductor wafers (see Patent Document 1).

### PRIOR ART DOCUMENT

Patent Document 1: Japanese Patent Laid-open Publication No. 2015-095579

### SUMMARY

In one exemplary embodiment, a bonding apparatus includes a first holder, a pushing member and a controller. The first holder is configured to hold a first substrate from below. The second holder is disposed above the first holder and configured to hold a second substrate from above. The pushing member is provided in the second holder and configured to push down a central portion of the second substrate. The first holder includes an outer attraction structure, an inner attraction structure and a transforming mechanism. The outer attraction structure is configured to attract a peripheral portion of the first substrate. The inner attraction structure is configured to attract a portion of the first substrate inside the peripheral portion. The transforming mechanism is configured to transform the outer attraction structure relative to the inner attraction structure. The controller acquires information of a height of the peripheral portion of the first substrate from a reference surface and controls the transforming mechanism based on the acquired information.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is a schematic plan view illustrating a configuration of a bonding system according to a first exemplary embodiment;

FIG. 2 is a schematic side view illustrating the configuration of the bonding system according to the first exemplary embodiment;

FIG. 3 is a schematic side view of an upper wafer and a lower wafer according to the first exemplary embodiment;

FIG. 4 is a schematic diagram illustrating a configuration of a bonding apparatus according to the first exemplary embodiment;

FIG. 5 is a schematic diagram illustrating the configuration of the bonding apparatus according to the first exemplary embodiment;

FIG. 6 is a schematic diagram illustrating configurations of a first holder and a second holder according to the first exemplary embodiment;

FIG. 7 is a schematic cross-sectional view illustrating the configuration of the first holder according to the first exemplary embodiment;

FIG. 8 is a schematic plan view illustrating the configuration of the first holder according to the first exemplary embodiment;

FIG. 9 is a schematic plan view illustrating positions of an attraction surface when an outer attraction structure is expanded according to the first exemplary embodiment;

FIG. 10 is a schematic cross-sectional view illustrating a configuration of a transforming mechanism according to the first exemplary embodiment;

FIG. 11 is a flowchart illustrating a sequence of processings performed by the bonding system according to the first exemplary embodiment;

FIG. 12 is a flowchart illustrating an example of a specific sequence of a processing described in a process S109;

FIG. 13 is a schematic cross-sectional view illustrating a state in which the outer attraction structure is expanded; and

FIG. 14 is a schematic plan view illustrating a configuration of the transforming mechanism according to a second exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, embodiments for a bonding apparatus and a bonding method according to the present disclosure (hereinafter, referred to as “exemplary embodiments”) will be described in detail with reference to the accompanying drawings. Further, it should be noted that the present disclosure is not limited by the exemplary embodiments. Furthermore, unless processing contents are contradictory, the various exemplary embodiments can be appropriately combined. In addition, in the various exemplary embodiments to be described below, same parts will be assigned same reference numerals, and redundant description will be omitted.

Further, in the following exemplary embodiments, expressions such as “constant,” “perpendicular,” “vertical” and “parallel” may be used. These expressions, however, do not imply strictly “constant”, “perpendicular,” “vertical” and “parallel”. That is, these expressions allow some tolerable errors in, for example, manufacturing accuracy, installation accuracy, or the like.

Moreover, in the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction. Further, a rotational direction around a vertical axis may be referred to as “0 direction.”

The bonding apparatus described in Patent Document 1 pushes down a central portion of a first substrate held by a first holder to bring it into contact with a central portion of a second substrate held by a second holder when the substrates are bonded to each other. Thus, the central portions of the two substrates are bonded by an intermolecular force, and a bonding region where the two substrates are bonded is expanded from the central portions toward outer edges of the substrates.

Herein, the first substrate or the second substrate may be thinner in the peripheral portion than in the other portions due to pre-bonding processes, such as chemical mechanical polishing (CMP) or etching. In this case, the height of the peripheral portion of the first or second substrate becomes reduced. Consequently, a reference point in the peripheral portion of the first substrate does not coincide with that of the second substrate. For example, if the peripheral portion of the second substrate is thinner than the other portions, after the first and second substrates are bonded to each other, a transformation component in the inwardly radial direction relative to the second substrate occurs in the first substrate. As a result, the bonding precision at the peripheral portion may deteriorate.

Accordingly, there is a need for a technique for appropriately correcting the height of a peripheral portion of a substrate.

### First Exemplary Embodiment

### <Configuration of Bonding System>

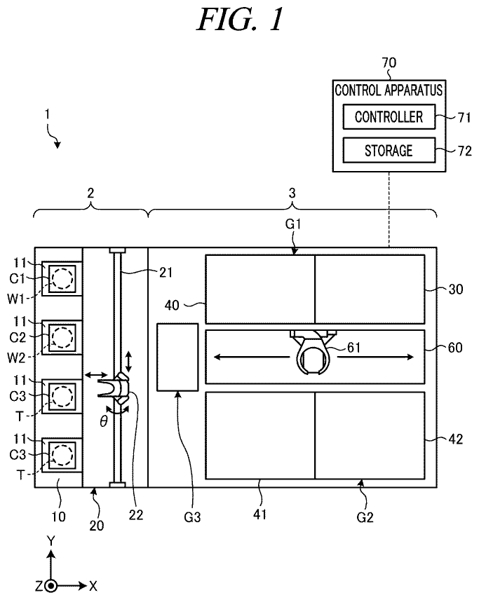

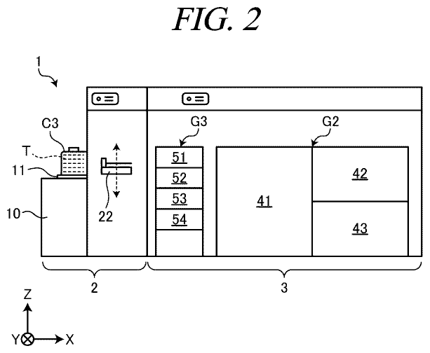

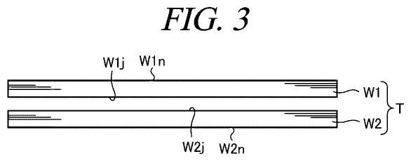

First, a configuration of a bonding system 1 according to a first exemplary embodiment will be explained with reference to FIG. 1 to FIG. 3. FIG. 1 is a schematic plan view illustrating a configuration of the bonding system 1 according to the first exemplary embodiment. FIG. 2 is a schematic side view illustrating the configuration of the bonding system 1 according to the first exemplary embodiment. FIG. 3 is a schematic side view of an upper wafer W1 and a lower wafer W2 according to the first exemplary embodiment.

The bonding system 1 shown in FIG. 1 and FIG. 2 is configured to form a combined wafer T by bonding a first substrate W1 and a second substrate W2 to each other.

The first substrate W1 is, for example, a semiconductor substrate, such as a silicon wafer or a compound semiconductor wafer, on which a plurality of electronic circuits is formed. The second substrate W2 is, for example, a bare wafer on which no electronic circuit is formed. The first substrate W1 and the second substrate W2 have the substantially same diameter.

Further, an electronic circuit may be formed on the second substrate W2. As the above-described compound semiconductor wafer, it may be possible to use, for example, a wafer containing gallium arsenide, silicon carbide, gallium nitride, indium phosphide or the like. However, the present disclosure is not limited thereto.

Hereinafter, the first substrate W1 will be referred to as “upper wafer W1,” and the second substrate W2 will be referred to as “lower wafer W2.” That is, the upper wafer W1 is an example of a first substrate, and the lower wafer W2 is an example of a second substrate. Further, the upper wafer W1 and lower wafer W2 will sometimes be collectively referred to “wafer W.”

In addition, hereinafter, as illustrated in FIG. 3, among plate surfaces of the upper wafer W1, the plate surface to be bonded to the lower wafer W2 will be referred to as “bonding surface W1j,” and the plate surface opposite to the bonding surface W1j will be referred to as “non-bonding surface W1n.” Likewise, among plate surfaces of the lower wafer W2, the plate surface to be bonded to the upper wafer W1 will be referred to as “bonding surface W2j,” and the plate surface opposite to the bonding surface W2j will be referred to as “non-bonding surface W2n.”

As depicted in FIG. 1, the bonding system 1 is equipped with a carry-in/out station 2 and a processing station 3. The carry-in/out station 2 and the processing station 3 are arranged in this order along the positive X-axis direction. Also, the carry-in/out station 2 and the processing station 3 are connected as one body.

The carry-in/out station 2 includes a placement table 10 and a transfer section 20. The placement table 10 is equipped with a multiple number of placement plates 11. Provided on the placement plates 11 are cassettes C1, C2 and C3 each of which accommodates therein a plurality of (e.g., 25 sheets of) substrates horizontally. For example, the cassette C1 accommodates therein upper wafers W1; the cassette C2, lower wafers W2; and the cassettes C3, combined wafers T.

The transfer section 20 is provided adjacent to the positive X-axis side of the placement table 10. This transfer section 20 is provided with a transfer path 21 extending in the Y-axis direction and a transfer device 22 configured to be movable along this transfer path 21.

The transfer device 22 is configured to be movable in the X-axis direction as well as in the Y-axis direction and pivotable around the Z-axis. The transfer device 22 serves to transfer the upper wafers W1, the lower wafers W2, and the combined wafers T between the cassettes C1 to C3 placed on the placement plates 11 and a third processing block G3 of the processing station 3 to be described later.

Further, the number of the cassettes C1 to C3 disposed on the placement plates 11 is not limited to the shown example. Moreover, in addition to the cassettes C1, C2, and C3, a cassette for collecting a defective substrate may be disposed on the placement plate 11.

The processing station 3 has a plurality of processing blocks equipped with various types of devices, for example, three processing blocks G1, G2 and G3. For example, the first processing block G1 is provided on the front side (positive Y-axis side of FIG. 1) of the processing station 3, and the second processing block G2 is provided on the rear side (negative Y-axis side of FIG. 1) of the processing station 3. Further, the third processing block G3 is provided on the carry-in/out station 2 side (negative X-axis side of FIG. 1) of the processing station 3.

The first processing block G1 is equipped with a surface modifying apparatus 30 configured to modify the bonding surface W1j of the upper wafer W1 and the bonding surface W2j of the lower wafer W2. The surfacy modifying apparatus 30 cuts a SiO₂ bond in the bonding surfaces W1j and W2j of the upper and lower wafers W1 and W2 to form a single bond of SiO, thus modifying the bonding surfaces W1j and W2j so that they can be easily hydrophilized afterwards.

Further, a surface hydrophilizing apparatus 40 is disposed in the first processing block G1. The surface hydrophilizing apparatus 40 is configured to hydrophilize the bonding surfaces W1j and W2j of the upper and lower wafers W1 and W2 with, for example, pure water, and also serves to clean the bonding surfaces W1j and W2j.

In the surface hydrophilizing apparatus 40, while rotating the upper wafer W1 or the lower wafer W2 held by, for example, a spin chuck, the pure water is supplied onto the upper wafer W1 or the lower wafer W2. Accordingly, the pure water supplied onto the upper wafer W1 or the lower wafer W2 is diffused on the bonding surface W1j of the upper wafer W1 or the bonding surface W2j of the lower wafer W2, so that the bonding surfaces W1j and W2j are hydrophilized.

In the present exemplary embodiment, the surface modifying apparatus 30 and the surface hydrophilizing apparatus 40 are arranged horizontally. However, the surface hydrophilizing apparatus 40 may be stacked on or under the surface modifying apparatus 30.

As shown in FIG. 2, the second processing block G2 is equipped with the bonding apparatus 41, a first temperature adjusting apparatus 42, and a second temperature adjusting apparatus 43. The bonding apparatus 41 is configured to bond the upper wafer W1 and the lower wafer W2, which have been hydrophilized, by an intermolecular force. Details of the bonding apparatus 41 will be described later.

The first temperature adjusting apparatus 42 is configured to adjust a temperature distribution of the upper wafer W1 before the combined wafer T is produced. The second temperature adjusting apparatus 43 is configured to adjust a temperature distribution of the lower wafer W2 before the combined wafer T is produced. Also, in the present exemplary embodiment, although the first temperature adjusting apparatus 42 and the second temperature adjusting apparatus 43 are provided separately from the bonding apparatus 41, they may be provided as a part of the bonding apparatus 41.

The third processing block G3 is equipped with a first position adjusting apparatus 51, a second position adjusting apparatus 52, and transition apparatuses 53 and 54 in this order from top to bottom, for example. Further, the positions of the individual apparatuses in the third processing block G3 are not limited to the example shown in FIG. 2. The first position adjusting apparatus 51 is configured to adjust a horizontal orientation of the upper wafer W1 and invert the upper wafer W1 so that the bonding surface W1j of the upper wafer W1 faces downwards. The second position adjusting apparatus 52 is configured to adjust a horizontal orientation of the lower wafer W2. The transition apparatus 53 is configured to temporarily place therein the upper wafer W1. Further, the transition apparatus 54 is configured to temporarily place therein the lower wafer W2 or the combined wafer T.

Further, as depicted in FIG. 1, a transfer section 60 is formed in an area surrounded by the first processing block G1, the second processing block G2, and the third processing block G3. A transfer device 61 is disposed in the transfer section 60. The transfer device 61 has a transfer arm configured to be movable in a vertical direction and a horizontal direction and pivotable around a vertical axis, for example.

This transfer device 61 is moved within the transfer section 60 to transfer the upper wafer W1, the lower wafer W2, and the combined wafer T to devices within the first processing block G1, the second processing block G2, and the third processing block G3 adjacent to the transfer section 60.

Further, the bonding system 1 is equipped with a control apparatus 70. The control apparatus 70 is configured to control an operation of the bonding system 1. The control apparatus 70 controls an operation of the bonding system 1 based on signals from a switch and various sensors.

The control apparatus 70 includes a microcomputer having a central processing unit (CPU), a read only memory (ROM), a random access memory (RAM), input/output ports, etc., and various types of circuits. The control apparatus 70 controls the operation of the bonding system 1 by reading out and executing a program stored in a storage 72.

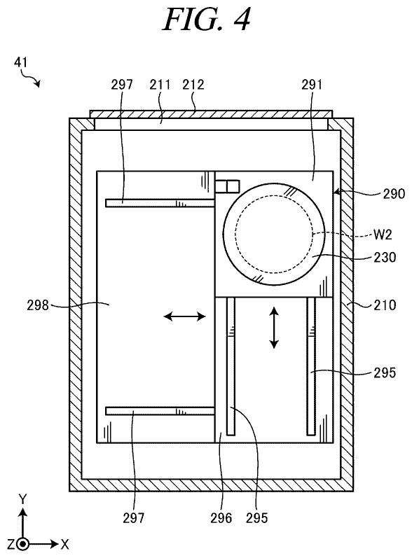

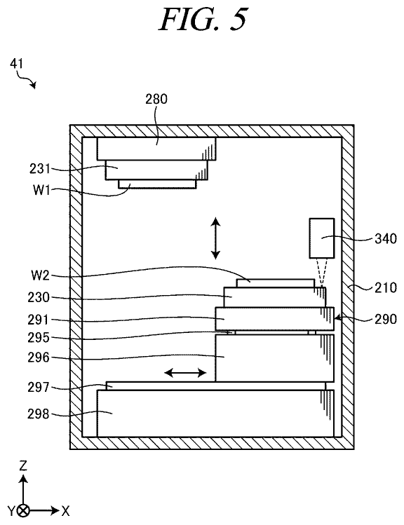

Hereinafter, an example of the bonding apparatus 41 according to the first exemplary embodiment will be described with reference to FIG. 4 and FIG. 5. FIG. 4 and FIG. 5 are schematic diagrams illustrating a configuration of the bonding apparatus 41 according to the first exemplary embodiment. As shown in FIG. 4, the bonding apparatus 41 is equipped with a processing container 210 having a sealable inside. A carry-in/out opening 211 is formed on a side surface of the processing container 210 on the transfer section 60 side, and an opening/closing shutter 212 is provided at the carry-in/out opening 211. The upper wafer W1, the lower wafer W2, and the combined wafer T are carried in and out through the carry-in/out opening 211.

As shown in FIG. 5, a first holder 230 and a second holder 231 are provided inside the processing container 210. The first holder 230 is configured to hold the lower wafer W2 from below while allowing the bonding surface W2j of the lower wafer W2 to face upwards. Further, the second holder 231 is disposed above the first holder 230, and configured to hold the upper wafer W1 from above while allowing the bonding surface W1j of the upper wafer W1 to face downwards. The first holder 230 and the second holder 231 are, for example, vacuum chucks.

The first holder 230 is supported by a first mover 291 provided below the first holder 230. Meanwhile, the second holder 231 is supported by a support member 280 provided on a ceiling surface of the processing container 210.

The first mover 291 is configured to move the first holder 230 in a horizontal direction (Y-axis direction) as described later. Further, the first mover 291 is configured to be able to move the first holder 230 in a vertical direction and to be able to rotate the first holder 230 around a vertical axis.

The first mover 291 is mounted on a pair of rails 295 provided on a lower surface of the first mover 291 and extending in the horizontal direction (Y-axis direction). The first mover 291 is configured to be movable along the rails 295. The rails 295 are provided on a second mover 296.

The second mover 296 is mounted on a pair of rails 297 provided on a lower surface of the second mover 296 and extending in the horizontal direction (X axis direction). The second mover 296 is configured to be movable along the rails 297. The pair of rails 297 is provided on a mounting member 298 provided on a bottom surface of the processing container 210.

The first mover 291 and the second mover 296 constitute a moving mechanism 290. The moving mechanism 290 moves the first holder 230 relative to the second holder 231. Further, the moving mechanism 290 moves the first holder 230 between a substrate transfer position and a bonding position.

The substrate transfer position is a position where the second holder 231 receives the upper wafer W1 from the transfer apparatus 61, the first holder 230 receives the lower wafer W2 from the transfer apparatus 61, and the first holder 230 delivers the combined wafer T to the transfer apparatus 61. The substrate transfer position is a position where a carry-out of the combined wafer T produced by n-th (n is a natural number equal to or greater than 1) bonding and a carry-in of the upper wafer W1 and the lower wafer W2 to be bonded by (n+1)-th bonding are performed in succession. The substrate transfer position is, for example, a position shown in FIG. 4 and FIG. 5.

When handing the upper wafer W1 over to the second holder 231, the transfer apparatus 61 advances to a space directly below the second holder 231. Further, when receiving the combined wafer T from the first holder 230 and handing the lower wafer W2 over to the first holder 230, the transfer apparatus 61 advances to a space directly above the first holder 230. The first holder 230 and the second holder 231 are moved sideways and a vertical distance between the first holder 230 and the second holder 231 is large so that the transfer apparatus 61 advances therebetween easily.

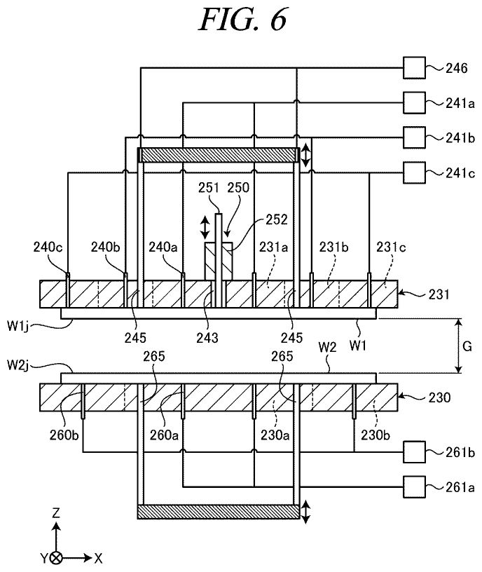

Meanwhile, the bonding position is a position (facing position) where the upper wafer W1 and the lower wafer W2 are made to face each other with a predetermined distance therebetween. The bonding position is, for example, a position shown in FIG. 6. At the bonding position, a vertical distance between the upper wafer W1 and the lower wafer W2 is narrower than that at the substrate transfer position. Further, at the bonding position, the upper wafer W1 and the lower wafer W2 overlap each other when viewed from the vertical direction, unlike at the substrate transfer position.

The moving mechanism 290 moves the relative positions of the first holder 230 and the second holder 231 in the horizontal directions (both the X-axis direction and the Y-axis direction) and the vertical direction. Although the moving mechanism 290 moves the first holder 230 in the present exemplary embodiment, it may move any one of the first holder 230 and the second holder 231, or both of them. Further, the moving mechanism 290 may rotate the first holder 230 or the second holder 231 around the vertical axis.

Hereinafter, configurations of the first holder 230 and the second holder 231 will be described with reference to FIG. 6. FIG. 6 is a schematic diagram illustrating the configurations of the first holder 230 and the second holder 231 according to the first exemplary embodiment.

As shown in FIG. 6, the first holder 230 is divided into a plurality of (for example, two) regions 230a and 230b along a radial direction of the first holder 230. These regions 230a and 230b are provided sequentially from a central portion of the first holder 230 toward an outer edge thereof. The region 230a is formed in a circular shape when viewed from the top, and the region 230b is formed in an annular shape when viewed from the top. The region 230b may have a plurality of arc-shaped zones (small regions) along a circumferential direction.

Suction lines 260a and 260b are independently provided in the regions 230a and 230b, respectively. Different vacuum pumps 261a and 261b are connected to the suction lines 260a and 260b, respectively. Thus, the first holder 230 is capable of vacuum-attracting the lower wafer W2 in each of the regions 230a and 230b.

The first holder 230 is equipped with a plurality of (for example, three) holding pins 265 configured to be movable in the vertical direction. The lower wafer W2 is placed on upper ends of the plurality of holding pins 265. Further, the lower wafer W2 may be vacuum-attracted to the upper ends of the plurality of holding pins 265.

The plurality of holding pins 265 is raised to be protruded from an attraction surface of the first holder 230. In this state, the plurality of holding pins 265 receives the lower wafer W2 from the transfer apparatus 61. Thereafter, the plurality of holding pins 265 is lowered to bring the lower wafer W2 into contact with the attraction surface of the first holder 230. Then, the first holder 230 vacuum-attracts the lower wafer W2 in the horizontal direction at a plurality of regions in the attraction surface.

As shown in FIG. 6, the second holder 231 is also divided into a plurality of (for example, three) regions 231a, 231b and 231c along a radial direction of the second holder 231. These regions 231a, 231b and 231c are provided sequentially from a central portion of the second holder 231 toward an outer edge thereof. The region 231a is formed in a circular shape when viewed from the top, and the regions 231b and 231c are formed in an annular shape when viewed from the top.

Suction lines 240a, 240b and 240c are independently provided in the regions 231a, 231b and 231c, respectively. Different vacuum pumps 241a, 241b and 241c are connected to the suction lines 240a, 240b and 240c, respectively. Thus, the second holder 231 is capable of vacuum-attracting the upper wafer W1 in each of the regions 231a, 231b and 231c.

The second holder 231 is equipped with a plurality of holding pins 245 configured to be movable in the vertical direction. The plurality of holding pins 245 is connected to a vacuum pump 246 and vacuum-attracts the upper wafer W1 by an operation of the vacuum pump 246. The upper wafer W1 is vacuum-attracted to lower ends of the plurality of holding pins 245. Instead of the plurality of holding pins 245, a ring-shaped attraction pad may be provided.

The plurality of holding pins 245 is lowered by a non-illustrated driver to be protruded from an attraction surface of the second holder 231. In this state, the plurality of holding pins 245 receives the upper wafer W1 from the transfer apparatus 61 by vacuum-attracting it. Thereafter, the plurality of holding pins 245 is raised to bring the upper wafer W1 into contact with the attraction surface of the second holder 231. Then, the second holder 231 vacuum-attracts the upper wafer W1 in the horizontal direction in each of the regions 231a, 231b and 231c by operations of the vacuum pumps 241a, 241b and 241c.

Further, the second holder 231 has, at a central portion thereof, a through hole 243 formed through the second holder 231 in the vertical direction. A pushing member 250 is inserted through the through hole 243. The pushing member 250 pushes down the central portion of the upper wafer W1 spaced apart from the lower wafer W2 to bring the upper wafer W1 into contact with the lower wafer W2.

The pushing member 250 has a pushing pin 251 and an outer cylinder 252 serving as an elevation guide for the pushing pin 251. The pushing pin 251 is inserted through the through hole 243 by, for example, a driver (not shown) having a motor therein, and protrudes from the attraction surface of the second holder 231 to push down the central portion of the upper wafer W1.

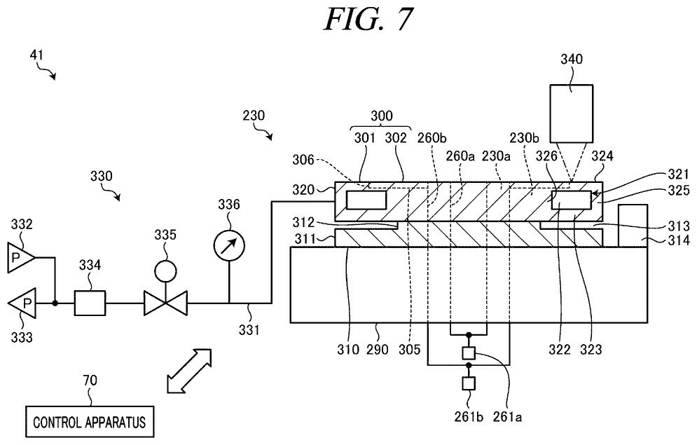

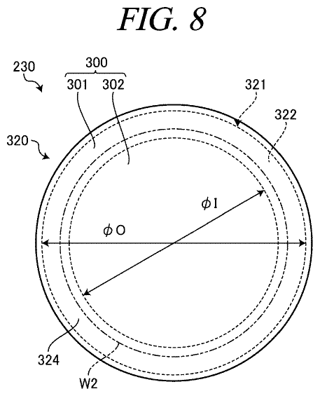

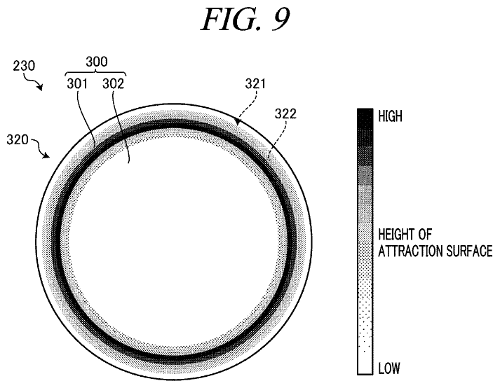

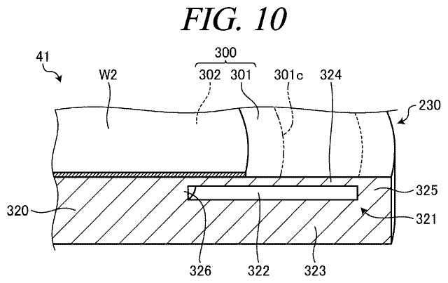

Hereinafter, a configuration of the first holder 230 according to the first exemplary embodiment will be described with reference to FIG. 7 to FIG. 10. FIG. 7 is a schematic cross-sectional view illustrating the configuration of the first holder 230 according to the first exemplary embodiment. FIG. 8 is a schematic plan view illustrating the configuration of the first holder 230 according to the first exemplary embodiment. FIG. 9 is a schematic plan view illustrating positions of an attraction surface when an outer attraction structure is expanded according to the first exemplary embodiment. FIG. 10 is a schematic cross-sectional view illustrating a configuration of a transforming mechanism according to the first exemplary embodiment. The first holder 230 functions to modify and maintain a height (shape) of a peripheral portion side of an attraction surface 300 to correct the height of the peripheral portion of the lower wafer W2. In FIG. 7 and the following drawings, the attraction surface 300 of the first holder 230 is illustrated as a flat shape. However, the attraction surface 300 may be provided with a plurality of ribs extending in the radial direction and a plurality of ribs wound in the circumferential direction.

Herein, the upper wafer W1 or the lower wafer W2 may be thinner in the peripheral portion than in the other portions due to pre-bonding processes, such as CMP or etching. In this case, the height of the peripheral portion of the upper wafer W1 or the lower wafer W2 becomes reduced. Consequently, a reference point in the peripheral portion of the upper wafer W1 does not coincide with that of the lower wafer W2. Therefore, bonding precision may deteriorate. For this reason, the first holder 230 controls the height of the peripheral portion side of the attraction surface 300 of the first holder 230 to expand or contract the bonding surface W2j based on the height of the peripheral portion of the lower wafer W2. Thus, a deviation between the reference points can be reduced.

Specifically, the first holder 230 has an outer attraction structure 301 configured to attract the peripheral portion of the lower wafer W2 and an inner attraction structure 302 configured to attract a portion of the lower wafer W2 inside the peripheral portion. The inner attraction structure 302 is formed in a circular shape when viewed from the top, and the outer attraction structure 301 is formed in an annular shape to be adjacent to the inner attraction structure 302 at an outside thereof.

The inner attraction structure 302 has the regions 230a and 230b (see FIG. 6). The outer attraction structure 301 overlaps a part of the region 230b, and is configured to apply an attracting pressure of the region 230b to the peripheral portion of the lower wafer W2. For example, the outer attraction structure 301 includes a plurality of internal paths 305 extending to the outside in the radial direction from the suction lines 260b, and attraction holes 306 respectively extending from the internal paths 305 to the attraction surface 300. With this configuration, the first holder 230 attracts an inner region including a central portion of the lower wafer W2 by the inner attraction structure 302, while attracting the peripheral portion of the lower wafer W2 by the outer attraction structure 301.

The first holder 230 internally and externally functions to transform the outer attraction structure 301 relative to the inner attraction structure 302. Specifically, the first holder 230 has a base member 310 provided on the moving mechanism 290 and a holding member 320 stacked on the base member 310 to hold the lower wafer W2 directly. Further, the first holder 230 also includes, in the holding member 320, a transforming mechanism 321 configured to transform the outer attraction structure 301. The transforming mechanism 321 is provided at a peripheral portion of the holding member 320.

The base member 310 has, in a side cross-sectional view along the vertical direction (see FIG. 7), a protruding shape in which a base 311 fixed to the moving mechanism 290 (a moving stage of the moving mechanism 290) and a short protruding portion 312 protruding vertically upwards from a central portion of the base 311 are provided. By fixing a surface (rear surface) of the holding member 320 opposite to the inner attraction structure 302 to an upper end surface of the protruding portion 312, the base member 310 supports the entire holding member 320 in the horizontal direction.

Thus, in the first holder 230, a clearance 313 which is a gap between members is formed between an upper surface of the base 311 of the base member 310 and a rear surface (for example, a lower surface) of the outer attraction structure 301 of the holding member 320 outside the protruding portion 312 in the radial direction. Herein, in the bonding apparatus 41, a mirror 314 configured to reflect light of a non-illustrated displacement meter that measures the horizontal position while being moved in three-dimensional directions by the moving mechanism 290 is disposed near the first holder 230. The mirror 314 and the base member 310 are spaced apart from each other on the moving stage of the moving mechanism 290. In a configuration where the base member 310 is transformed according to the transformation with the transforming mechanism 321 of the first holder 230, the transformation may affect the reflection of the mirror 314 adjacent to the base member 310.

For this reason, the first holder 230 does not support the rear surface of the outer attraction structure 301 with the base member 310, and, thus, it is possible to suppress the influence of the transformation of the outer attraction structure on the base member 310. That is, even in the configuration in which the outer attraction structure 301 is transformed, the bonding apparatus 41 stabilizes the reflection of the mirror 314 and thus improves the measurement precision near the first holder 230. Therefore, positioning of the first holder 230 can be carried out stably.

Further, the holding member 320 according to the present exemplary embodiment has a transformation space 322 constituting the transforming mechanism 321 under the outer attraction structure 301 (i.e., at an inside of the holding member 320 overlapping the outer attraction structure 301 in the vertical direction). When viewed on a cross-section along the vertical direction, the transformation space 322 is a space surrounded by a lower wall 323, an upper wall 324, an outer peripheral wall 325, and an inner peripheral wall 326 of the holding member 320. The transformation space 322 is formed to have a rectangular shape with a long side in the horizontal direction in a state where the transformation space 322 has a pressure equal to a pressure outside the holding member 320. The lower wall 323, the upper wall 324, the outer peripheral wall 325, and the inner peripheral wall 326 may be an integrally molded member, or some of the walls may be formed of a different member from the others. For example, in the holding member 320, the lower wall 323 may be formed of a (hard) material having a high elastic modulus, whereas the upper wall 324, the outer peripheral wall 325, and the inner peripheral wall 326 may be formed of a (soft) material having a lower elastic modulus than the lower wall 323.

The upper wall 324 forming the transformation space 322 is provided with the internal paths 305 and the attraction holes 306. A thickness of a thick portion of the upper wall 324 (between a front surface (e.g., an upper surface) of the outer attraction structure 301 and the transformation space 322) is set to be smaller than a thickness of a thick portion of the lower wall 323 (between a rear surface (e.g., a lower surface) of the outer attraction structure 301 and the transformation space 322). Accordingly, when an internal pressure of the transformation space 322 fluctuates, the upper wall 324 is greatly transformed, whereas most of the lower wall 323, the outer peripheral wall 325, and the inner peripheral wall 326 are not transformed. For this reason, in the first holder 230, the upper wall 324 is transformed according to the fluctuations in the internal pressure of the transformation space 322. Thus, the outer attraction structure 301 can be transformed stably and reliably.

Further, as shown in FIG. 8, the transformation space 322 is formed in an annular (ring) shape that goes around the inside of the holding member 320 forming the attraction surface 300. For this reason, the internal pressure of the transformation space 322 is uniformly applied in the circumferential direction of the holding member 320. Therefore, in the first holder 230, the outer attraction structure 301 can be uniformly transformed as a whole over the entire circumference according to the fluctuations in the internal pressure of the transformation space 322.

For example, when the internal pressure of the transformation space 322 is increased, the upper wall 324 is expanded over the entire circumference of the holding member 320 as shown in FIG. 9. Further, in FIG. 9, a white color indicates the height (position) of the inner attraction structure 302 in the vertical direction, which is a reference on the attraction surface 300. Furthermore, as the color becomes darker, it indicates that the height of the attraction surface 300 increases. In this way, when the transforming mechanism 321 is transformed, the first holder 230 modifies the height of the outer attraction structure 301 over the entire circumference. Thus, the first holder 230 can transform the peripheral portion of the lower wafer W2 uniformly.

Referring back to FIG. 7, in the bonding apparatus 41, a fluid supply/exhaust device 330 configured to supply or exhaust a fluid for transformation to/from the transformation space 322 is connected to a port in a side surface of the holding member 320. In the present exemplary embodiment, the fluid for transformation is air. However, the fluid for transformation is not merely limited to the air, and it may be an inert gas, such as nitrogen (N₂), or a liquid, such as water or oil.

The fluid supply/exhaust device 330 has a supply/exhaust path 331 that is connected to the port of the holding member 320 and extended to the outside of the processing container 210. Further, the fluid supply/exhaust device 330 is equipped with pumps (a booster pump 332 and a decompression pump 333), a regulator 334, a valve 335, and a pressure sensor 336 that are arranged in sequence from an upstream side of the supply/exhaust path 331 toward a downstream side thereof.

The booster pump 332 and the decompression pump 333 are branched from an upstream side of, for example, the regulator 334, and configured to be operated independently under the control of the control apparatus 70. The booster pump 332 supplies the air to the holding member 320 to increase the internal pressure of the transformation space 322. The decompression pump 333 exhausts the air from the holding member 320 to reduce the internal pressure of the transformation space 322.

The regulator 334 is, for example, an electro-pneumatic regulator, and serves to adjust the pressure of the air flowing through the supply/exhaust path 331 to a target pressure instructed by the control apparatus 70. Further, the fluid supply/exhaust device 330 is not limited to being equipped with only one regulator 334. For example, the regulator 334 may be applied to each of the booster pump 332 and the decompression pump 333.

The valve 335 serves to open and close a flow path within the supply/exhaust path 331 under the control of the control apparatus 70. For example, the valve 335 may be an air-operated valve (AOV) having a function of opening and closing the supply/exhaust path 331 and a function of opening it to the atmosphere to introduce or exhaust the air. With this configuration, by opening the valve 335 to the atmosphere when the transformation of the outer attraction structure 301 is completed, the transforming mechanism 321 can be restored immediately. Further, the number of valves 335 is not limited to one. For example, the valve 335 may be provided in each of the booster pump 332 and the decompression pump 333.

The pressure sensor 336 serves to detect a pressure of the air supplied to or exhausted from the holding member 320, and transmits the detection information to the control apparatus 70. Based on this detection information from the pressure sensor 336, the control apparatus 70 adjusts the amount of the air supplied to the transforming mechanism 321, and closes the valve 335 at an appropriate timing. In a state where the valve 335 is closed, the transformation space 322 is maintained at a predetermined internal pressure. Thus, the transformed state of the upper wall 324 can be maintained.

Further, the bonding apparatus 41 is equipped with a displacement sensor (measurement apparatus) 340 vertically above the first holder 230 in order to detect the height of the peripheral portion of the lower wafer W2. For example, the displacement sensor 340 is disposed above the outer attraction structure 301 of the first holder 230 which is located at the substrate transfer position. The displacement sensor 340 performs measurement by, for example, a confocal method, a spectral interferometry method, or a triangulation method. A light source of the displacement sensor 340 is an LED or a laser. The displacement sensor 340 is connected to the control apparatus 70, and serves to measure the height of the peripheral portion of the lower wafer W2 based on the attraction surface 300 and transmit the measurement information to the control apparatus 70.

The control apparatus 70 may operate the transforming mechanism 321 based on the measurement result acquired by the displacement sensor 340. For example, when the height of the peripheral portion of the lower wafer W2 is in a threshold range including a target height, the control apparatus 70 stops the transformation with the transforming mechanism 321. When the height of the peripheral portion of the lower wafer W2 is out of the threshold range including the target height, the control apparatus 70 transforms the transforming mechanism 321 based on the amount of deviation from the target height. In FIG. 7, the single displacement sensor 340 is provided at a position facing the outer attraction structure 301, but a plurality of displacement sensors 340 may be provided along the circumferential direction of the outer attraction structure 301. A first displacement meter configured to measure the thickness of the lower wafer W2 may be used as the displacement sensor 340. Alternatively, a non-illustrated imaging device configured to image a side surface of the lower wafer W2 may be used instead of the displacement sensor 340. The height of the peripheral portion of the lower wafer W2 may be acquired, based on the image data of the lower wafer W2 acquired by the imaging device.

Further, in the bonding apparatus 41 according to the present exemplary embodiment, when the lower wafer W2 is placed on the attraction surface 300 of the first holder 230, the lower wafer W2 is transformed by using transformation at a widthwise intermediate portion of the outer attraction structure 301 (the transformation space 322). Herein, the widthwise intermediate portion of the outer attraction structure 301 refers to the vicinity of a widthwise intermediate position 301c of the outer attraction structure 301. For example, the widthwise intermediate portion is a central area when the outer attraction structure 301 is divided into three equal parts in the width direction. For this reason, as shown in FIG. 10, when the lower wafer W2 is held on the attraction surface 300, the bonding apparatus 41 determines a position of the lower wafer W2 such that the outer edge of the lower wafer W2 is located near the widthwise intermediate position 301c of the outer attraction structure 301. Further, in FIG. 10, the widthwise intermediate position 301c of the outer attraction structure 301 is marked by a dashed-dotted line for convenience sake.

In order to place the outer edge of the lower wafer W2 near the widthwise intermediate position 301c of the outer attraction structure 301, the range of the formation of the transformation space 322 is designed to have a size according to the size of the lower wafer W2. For example, when a diameter of the lower wafer W2 is 300 mm, a diameter φI of the inner peripheral wall 326 of the transformation space 322 may be set to be in the range of 270 mm to 280 mm, and a diameter φO of the outer peripheral wall 325 of the transformation space 322 may be set to be in the range of 340 mm to 350 mm (see FIG. 8). In the present exemplary embodiment, the diameter φI of the inner peripheral wall 326 is set to be 276 mm, and the diameter φO of the outer peripheral wall 325 is set to be 346 mm. Accordingly, a width of the outer attraction structure 301 (the transformation space 322) becomes 70 mm, and the widthwise intermediate position 301c of the outer attraction structure 301 becomes 35 mm. A distance from the center of the first holder 230 to the widthwise intermediate position 301c of the outer attraction structure 301 becomes 311 mm (=276 mm+35 mm). A boundary between the outer attraction structure 301 and the inner attraction structure 302 may be defined by the inner peripheral wall 326. The outer attraction structure 301 may be regarded as the entire holding member 320 outside the inner peripheral wall 326 in the radial direction, or may be regarded as the formation range of the transformation space 322 (between the outer peripheral wall 325 and the inner peripheral wall 326). Alternatively, the boundary between the outer attraction structure 301 and the inner attraction structure 302 may be defined by a supporting portion (the protruding portion 312) and a non-supporting portion (the clearance 313) of the base member 310 (see FIG. 7). Also, it is desirable that the ratio of the width of the outer attraction structure 301 to the radius of the inner attraction structure 302 is set to be in the range of about ⅕ to about ⅗.

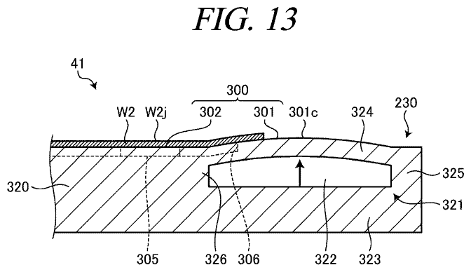

In the bonding apparatus 41, the outer edge of the lower wafer W2 is placed near the widthwise intermediate position 301c of the outer attraction structure 301, and, thus, the influence of the transformed shape of the transforming mechanism 321 near the widthwise intermediate position 301c may be imposed on the upper wafer W1 and the lower wafer W2 when the transforming mechanism 321 is transformed. For example, when the lower wafer W2 becomes thinner in the peripheral portion than in the other portions and the height of the peripheral portion of the lower wafer W2 is smaller than a threshold range including a target height, an operation of expanding the transforming mechanism 321 (the upper wall 324) of the transformation space 322 is performed in order for the height of the peripheral portion of the bonding surface W2j to be in the threshold range (see FIG. 13). In this way, the bonding apparatus 41 is capable of correcting the height of the peripheral portion of the lower wafer W2 with high precision by using the shape of the central portion of the outer attraction structure 301 that has been transformed. Since the height of the peripheral portion of the lower wafer W2 is corrected, the upper wafer W1 and the lower wafer W2 are bonded to each other in a state where a transformation component directed radially inward is applied to the upper wafer W1. Thus, the transformation components of the upper wafer W1 and the lower wafer W2 are cancelled each other out. As a result, it is possible to suppress the deterioration in bonding precision.

### <Specific Operation of Bonding System>

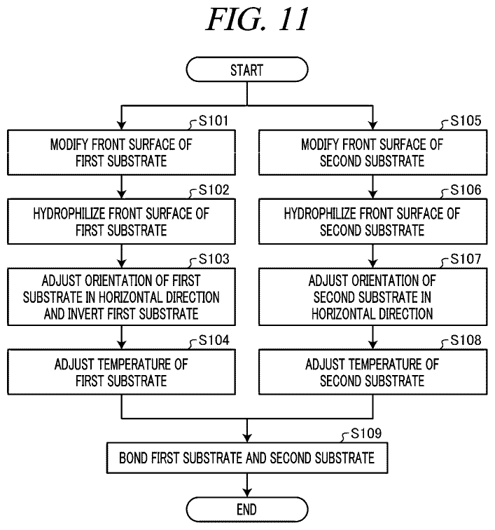

Hereinafter, a specific operation of the bonding system 1 according to the first exemplary embodiment will be described with reference to FIG. 11. FIG. 11 is a flowchart illustrating a sequence of processings performed by the bonding system 1 according to the first exemplary embodiment. The various processes shown in FIG. 11 are executed under the control of the control apparatus 70.

First, the cassette C1 accommodating a plurality of upper wafers W1, the cassette C2 accommodating a plurality of lower wafers W2, and the empty cassette C3 are mounted on the mounting stage 10 of the carry-in/out station 2. Thereafter, the upper wafer W1 in the cassette C1 is taken out by the transfer apparatus 22 and transferred to the transition apparatus 53 disposed in the third processing block G3 of the processing station 3.

Then, the upper wafer W1 is transferred to the surface modifying apparatus 30 of the first processing block G1 by the transfer apparatus 61. In the surface modifying apparatus 30, an oxygen gas, which is a processing gas, is excited into plasma to be ionized under a decompressed atmosphere. Then, the bonding surface of the upper wafer W1 is irradiated with the oxygen ions. Thus, the bonding surface of the upper wafer W1 is treated with plasma to be modified (process S101).

Thereafter, the upper wafer W1 is transferred to the surface hydrophilizing apparatus 40 of the first processing block G1 by the transfer apparatus 61. In the surface hydrophilizing apparatus 40, pure water is supplied onto the upper wafer W1 while the upper wafer W1 held by the spin chuck is rotated. Thus, the bonding surface of the upper surface W1 is hydrophilized. Also, the bonding surface of the upper surface W1 is cleaned with the pure water (process S102).

Thereafter, the upper wafer W1 is transferred to the first position adjusting apparatus 51 of the third processing block G3 by the transfer apparatus 61. Then, the horizontal orientation of the upper wafer W1 is adjusted by the first position adjusting apparatus 51, and the upper wafer W1 is inverted (process S103). Thus, a notch of the upper wafer W1 is directed in a predetermined direction, and the bonding surface W1j of the upper wafer W1 is turned to face downwards.

Then, the upper wafer W1 is transferred to the first temperature adjusting apparatus 42 of the second processing block G2 by the transfer apparatus 61. The temperature of the upper wafer W1 is adjusted by the first temperature adjusting apparatus 42 (process S104). The temperature adjustment over the upper wafer W1 is performed in a state where the bonding surface W1j of the upper wafer W1 faces downwards. Thereafter, the upper wafer W1 is transferred to the bonding apparatus 41 by the transfer apparatus 61.

The above-described processing including the processes S101 to S104 on the upper surface W1 is also performed on the lower wafer W2. First, the lower wafer W2 in the cassette C2 is taken out by the transfer apparatus 22 and transferred to the transition apparatus 53 disposed in the third processing block G3.

Then, the lower wafer W2 is transferred to the surface modifying apparatus 30 by the transfer apparatus 61, and the bonding surface W2j of the lower wafer W2 is modified (process S105). Thereafter, the lower wafer W2 is transferred to the surface hydrophilizing apparatus 40 by the transfer apparatus 61. Thus, the bonding surface W2j of the lower wafer W2 is hydrophilized and cleaned (process S106).

Thereafter, the lower wafer W2 is transferred to the second position adjusting apparatus 52 by the transfer apparatus 61. Then, the horizontal orientation of the lower wafer W2 is adjusted by the second position adjusting apparatus 52 (process S107). Thus, a notch of the lower wafer W2 is directed in a predetermined direction.

Then, the lower wafer W2 is transferred to the second temperature adjusting apparatus 43 of the second processing block G2 by the transfer apparatus 61. The temperature of the lower wafer W2 is adjusted by the second temperature adjusting apparatus 43 (process S108). The temperature adjustment over the lower wafer W2 is performed in a state where the bonding surface W2j of the lower wafer W2 faces upwards. Thereafter, the lower wafer W2 is transferred to the bonding apparatus 41 by the transfer apparatus 61.

Then, the upper wafer W1 and the lower wafer W2 are bonded to each other by the bonding apparatus 41 to produce the combined wafer T (process S109). Details of the process S109 will be described later. Thereafter, the combined wafer T is transferred to the transition apparatus 54 of the third processing block G3 by the transfer apparatus 61.

Thereafter, the combined wafer T is transferred to the cassette C3 on the mounting stage 10 by the transfer apparatus 22. Thus, a series of processes is completed.

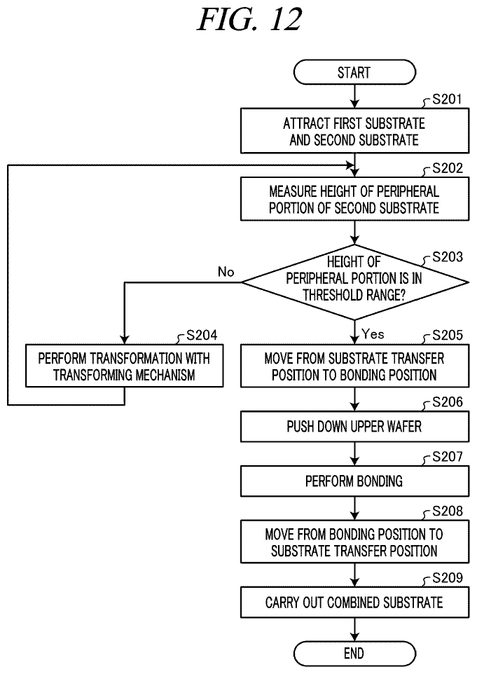

Hereinafter, an example of a specific sequence of a processing for producing the combined wafer T in the process S109 shown in FIG. 11 will be described with reference to FIG. 12 and FIG. 13. FIG. 12 is a flowchart illustrating an example of a specific sequence of a processing described in the process S109. FIG. 13 is a schematic cross-sectional view illustrating a state in which the outer attraction structure 301 is expanded.

First, a controller 71 controls the first holder 230 to attract and hold the lower wafer W2, which has been carried into the bonding apparatus 41, from below. Likewise, the controller 71 controls the second holder 231 to attract and hold the upper wafer W1, which has been carried into the bonding apparatus 41, from above (process S201). In this case, the relative positions of the first holder 230 and the second holder 231 are at the substrate transfer position as shown in FIG. 5.

Then, the controller 71 acquires the height information of the peripheral portion of the lower wafer W2 based on the attraction surface 300 from the displacement sensor 340 (process S202). For example, the controller 71 controls the moving mechanism 290 (see FIG. 4 and FIG. 5) to move the first holder 230 in the horizontal direction such that a certain point in the peripheral portion of the lower wafer W2 is located directly under the displacement sensor 340. Thereafter, the controller 71 acquires the height information at the certain point from the displacement sensor 340. By repeating the processing of moving the first holder 230 and the processing of acquiring the height information from the displacement sensor 340, the controller 71 can acquire the height information in the entire circumference of the peripheral portion of the lower wafer W2. For example, the controller 71 performs a subsequent processing using an average value of the heights in the entire circumference of the peripheral portion of the lower wafer W2. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

Then, the controller 71 determines whether the height of the peripheral portion of the lower wafer W2 based on the attraction surface 300 is in the threshold range including the target height (process S203). The target height is determined when a non-illustrated measurement apparatus measures the thickness of the lower wafer W2 before the lower wafer W2 is carried into the bonding system 1. For example, the thickness of the central portion of the lower wafer W2 measured by the measurement apparatus, or an average value of the thicknesses of a plurality of points in the lower wafer W2 may be determined as the target height.

When the height of the peripheral portion of the lower wafer W2 is out of the threshold range including the target height (No in process S203), the controller 71 performs an operation of transforming the transforming mechanism 321 (process S204).

In the transformation operation, the controller 71 releases the attraction of the lower wafer W2 by the first holder 230.

Then, the controller 71 performs a boosting processing of increasing the internal pressure of the transformation space 322 based on the amount of deviation between the height of the peripheral portion of the lower wafer W2 and the target height. Specifically, the controller 71 supplies the air into the transformation space 322 through the fluid supply/exhaust device 330, and, thus, the upper wall 324 is raised (expanded) vertically upwards as shown in FIG. 13. In this case, the upper wall 324 is curved in an arc shape with the widthwise intermediate position 301c as an apex. For this reason, after the first holder 230 is transformed, the lower wafer W2 whose outer edge is attracted to an inner side than the widthwise intermediate position 301c of the outer attraction structure 301 in the radial direction is held by the first holder 230 while having a shape inclined vertically upwards toward the outside in the radial direction.

The controller 71 may acquire the amount of air supplied to the transformation space 322 based on a table which has been stored in advance in the storage 72 and correlates the amount of deviation between the height of the peripheral portion of the lower wafer W2 and the target height with the amount of air supplied.

Accordingly, for example, if the lower wafer W2 becomes thinner in the peripheral portion than in the other portions due to the pre-bonding processes and the height of the peripheral portion of the lower wafer W2 becomes reduced, the height of the peripheral portion of the lower wafer W2 can be appropriately corrected when the lower wafer W2 is attracted. Thus, the lower wafer W2 can be held in this state.

The controller 71 monitors the height of the peripheral portion of the lower wafer W2 while repeating the process S202 and the process S203 when the transforming mechanism 321 is transformed in a process S204. In the process S203, when the height of the peripheral portion of the lower wafer W2 is in the threshold range including the target height (Yes in process S203), the controller 71 stops the transformation with the transforming mechanism 321 to attract and hold the lower wafer W2 again by the first holder 230, and proceeds to a process S205. As described above, if the outer attraction structure 301 is expanded, the lower wafer W2 is held in the state where the peripheral portion of the lower wafer W2 is transformed. Also, when the height of the peripheral portion of the lower wafer W2 is in the threshold range including the target height based on the initial measurement by the displacement sensor 340, the controller 71 does not perform the transformation with the transforming mechanism 321, but proceeds to a process S205.

Then, the controller 71 controls the moving mechanism 290 to move the relative positions of the first holder 230 and the second holder 231 from the substrate transfer position to the bonding position shown in FIG. 6 (process S205). In the process S205, the controller 71 adjusts the horizontal positions of the upper wafer W1 and the lower wafer W2.

A plurality of predetermined reference points is formed on the bonding surface W1j of the upper wafer W1. Also, a plurality of predetermined reference points is formed on the bonding surface W2j of the lower wafer W2. As the reference points, for example, predetermined patterns formed on the upper wafer W1 and the lower wafer W2, respectively, are used. The number of the reference points can be determined as required.

The horizontal positions of the upper wafer W1 and the lower wafer W2 may be adjusted by using, for example, non-illustrated first and second imaging devices, respectively. The first imaging device serves to image the reference points formed on the lower surface (the bonding surface W1j) of the upper wafer W1, and the second imaging device serves to image the reference points formed on the upper surface (the bonding surface W2j) of the lower wafer W2.

The first imaging device and the second imaging device output the acquired image data to the controller 71. The controller 71 controls the moving mechanism 290 to move the first holder 230 in the horizontal direction based on the image data such that the reference points of the upper wafer W1 respectively coincide with the reference points of the lower wafer W2. Further, the controller 71 controls the moving mechanism 290 to rotate the first holder 230 around the vertical axis such that the reference points of the upper wafer W1 respectively coincide with the reference points of the lower wafer W2. In this way, the horizontal positions of the first holder 230 and the second holder 231 can be adjusted, and the horizontal positions of the upper wafer W1 and the lower wafer W2 can be adjusted.

Further, in the process S205, the controller 71 adjusts vertical positions of the upper wafer W1 and the lower wafer W2. Specifically, the controller 71 controls the moving mechanism 290 to move the first holder 230 vertically upwards. As a result, a distance G (see FIG. 6) between the bonding surface W2j of the lower wafer W2 and the bonding surface W1j of the upper wafer W1 becomes a predetermined distance of, e.g., 80 μm to 200 μm. The adjustment of the distance G is performed by using, for example, non-illustrated first and second displacement meters. The first displacement meter measures the thickness of the lower wafer W2 held by the first holder 230. The second displacement meter measures the thickness of the upper wafer W1 held by the second holder 231. The measurement of the thickness is performed when the moving mechanism 290 moves the second holder 231 in the horizontal direction, for example.

The first displacement meter and the second displacement meter output the measured data to the controller 71. The controller 71 controls the moving mechanism 290 based on the data measured by the first displacement meter and the data measured by the second displacement meter, and adjusts the vertical position of the first holder 230 such that the distance G becomes a set value.

Then, the controller 71 stops the operation of the vacuum pump 241, and releases the attraction of the upper wafer W1 in the region 231a (see FIG. 5). Thereafter, the controller 71 pushes down the central portion of the upper wafer W1 by lowering the pushing pin 251 of the pushing member 250 to bring the upper wafer W1 into contact with the lower wafer W2 (process S206). As a result, the central portions of the upper and lower wafers W1 and W2 are bonded to each other.

Since the bonding surface W1j of the upper wafer W1 and the bonding surface W2j of the lower wafer W2 are modified, a van der Waals force (intermolecular force) is first generated between the bonding surfaces W1j and W2j. Thus, the bonding surfaces W1j and W2j are bonded to each other. Further, since the bonding surface W1j of the upper wafer W1 and the bonding surface W2j of the lower wafer W2 have been hydrophilized, hydrophilic groups (e.g., OH groups) are hydrogen-bonded, which allows the bonding surfaces W1j and W2j to be firmly bonded to each other.

Subsequently, the controller 71 stops the operation of the vacuum pump 241b, and release the attraction of the upper wafer W1 in the region 231b. Afterwards, the controller 71 stops the operation of the vacuum pump 241c, and releases the attraction of the upper wafer W1 in the region 231c.

In this way, the vacuum attraction of the upper wafer W1 is released step by step from the central portion toward the periphery of the upper wafer W1. Thus, the upper wafer W1 drops and comes into contact with the lower wafer W2 step by step. Then, the bonding of the upper wafer W1 and the lower wafer W2 proceeds sequentially from the central portions toward the peripheries of the upper and lower wafers W1 and W2 (process S207). As a result, the entire bonding surface W1j of the upper wafer W1 and the entire bonding surface W2j of the lower wafer W2 come into contact with each other. Thus, the upper wafer W1 and the lower wafer W2 are bonded to each other and the combined wafer T is acquired. Then, the controller 71 raises the pushing pin 251 to its original position.

After the combined wafer T is produced, the controller 71 controls the moving mechanism 290 to move the relative positions of the first holder 230 and the second holder 231 from the bonding positions shown in FIG. 6 to the substrate transfer positions shown in FIG. 4 and FIG. 5 (process S208). For example, the controller 71 controls the moving mechanism 290 to lower the first holder 230 to widen the vertical distance between the first holder 230 and the second holder 231. Then, the controller 71 controls the moving mechanism 290 to move the first holder 230 sideways. Thus, the first holder 230 and the second holder 231 are placed sideways apart.

Thereafter, the controller 71 controls the transfer apparatus 61 to carry out the combined wafer T (process S209). Specifically, the controller 71 first releases the attraction of the combined wafer T by the first holder 230. Then, the controller 71 raises the plurality of holding pins 265 to hand the combined wafer T over to the transfer apparatus 61. Thereafter, the controller 71 lowers the plurality of holding pins 265 to their original positions.

As described above, the bonding apparatus 41 according to the present exemplary embodiment can appropriately correct the height of the peripheral portion of the lower wafer W2 by transforming the outer attraction structure 301 relative to the inner attraction structure 302 with the transforming mechanism 321. This makes it possible, for example, to sufficiently correct the height of the peripheral portion of the lower wafer W2 when the height of the peripheral portion of the bonding surface W2j of the lower wafer W2 is small, which enables the lower wafer W2 to be bonded to the upper wafer W1. As a result, the bonding apparatus 41 can produce the combined wafer T in which the deviation between the reference points of the upper wafer W1 and the lower wafer W2 is reduced.

Also, the controller 71 controls the first holder 230 to hold the lower wafer W2, acquires the height information of the peripheral portion of the lower wafer W2 based on the attraction surface 300 from the displacement sensor 340, and controls the transforming mechanism 321 based on the acquired information to transform the outer attraction structure 301. Thereafter, the controller 71 controls the outer attraction structure 301 and the inner attraction structure 302 to attract the lower wafer W2.

In this way, the controller 71 first releases the attraction of the lower wafer W2, performs the transformation of the first holder 230 with the transforming mechanism 321, and attracts the lower wafer W2 again. As a result, it becomes difficult to apply the pressure to the lower wafer W2 from the first holder 230 during the transformation. Further, after releasing the attraction of the lower wafer W2, the controller 71 may raise the plurality of holding pins 265 and perform the transformation in the state where the lower wafer W2 is not in contact with the first holder 230.

While the foregoing description has focused on measuring the height of the peripheral portion of the lower wafer W2, the present disclosure is not limited thereto. The height of the peripheral portion of the upper wafer W1 may also be measured. For example, the bonding apparatus 41 may further include a non-illustrated displacement sensor for measuring the height of the peripheral portion of the upper wafer W1. In this case, the controller 71 acquires the height information of the peripheral portion of the upper wafer W1 from this displacement sensor in the process S202 shown in FIG. 12, and determines whether the sum of the heights of the peripheral portions of the lower wafer W2 and the upper wafer W1 is in the threshold range including the target sum of heights in the process S203. That is, the controller 71 may control the transforming mechanism 321 based on the height information of the peripheral portions of the upper and lower wafers W1 and W2. Alternatively, the controller 71 may control the transforming mechanism 321 based only on the height information of the peripheral portion of the upper wafer W1.

Moreover, the amount of deviation between the height of the peripheral portion of the lower wafer W2 and the target height may be corrected not only in the bonding processing, but also in a subsequent photolithography process.

### Second Exemplary Embodiment

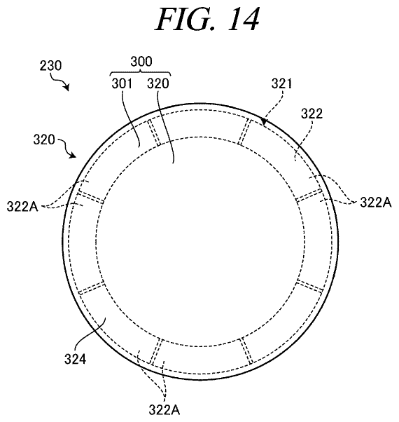

FIG. 14 is a schematic plan view illustrating a configuration of the transforming mechanism 321 according to a second exemplary embodiment. As shown in FIG. 14, the transforming mechanism 321 configured to transform the outer attraction structure 301 may have a plurality of transformation spaces 322A separated along the circumferential direction of the second holder 231, and air may be supplied to and exhausted from each of the plurality of transformation spaces 322A individually. With this configuration, the first holder 230 can individually adjust the amount of transformation in the circumferential direction of the outer attraction structure 301 based on the heights measured from a plurality of points in the peripheral portion of the lower wafer W2. That is, when the heights are measured from the plurality of points in the peripheral portion of the lower wafer W2 in the process S202 shown in FIG. 12, the controller 71 supplies the air to the transformation spaces 322A corresponding to the measurement points based on the amounts of transformation between the measured heights and the target height in the subsequent processes S203 and S204. That is, the bonding apparatus 41 can appropriately perform the correction based on a difference in height of the peripheral portion of the lower wafer W2. Although eight transformation spaces 322A separated from each other are illustrated in FIG. 16, the number of divisions and the volume of each space can be designed as required. In the present exemplary embodiment, it has been described that the heights are measured from a plurality of points in the peripheral portion of the lower wafer W2, but the method of measuring the height of the peripheral portion is not limited thereto. For example, the height of the peripheral portion of the lower wafer W2 may also be measured while rotating the lower wafer W2 by 360°.

### Third Exemplary Embodiment

In the first exemplary embodiment, it has been described that the height of the peripheral portion of the lower wafer W2 is measured inside the bonding apparatus 41, but the present disclosure is not limited thereto. The height of the peripheral portion of the lower wafer W2 may also be measured outside the bonding apparatus 41. For example, the height of the peripheral portion of the lower wafer W2 may be measured by a non-illustrated measurement apparatus provided inside the bonding system 1. The measurement apparatus measures the height information of the peripheral portion of the lower wafer W2 and outputs it to the control apparatus 70, and the control apparatus 70 controls the transforming mechanism 321 based on the acquired information. Also, the height of the peripheral portion of the lower wafer W2 may be measured by a non-illustrated measurement apparatus provided outside the bonding system 1. In this case, the measurement apparatus outputs the measured height information of the peripheral portion of the lower wafer W2 to the control apparatus 70 via a network, and the control apparatus 70 controls the transforming mechanism 321 based on the acquired information.

In this case, the processing in the process S202 shown in FIG. 12 may be omitted, and, thus, it is possible to improve the throughput of the processing.

### Fourth Exemplary Embodiment

In the first exemplary embodiment, it has been described that when the transforming mechanism 321 performs the transformation, the controller 71 releases the attraction of the lower wafer W2, performs the transformation of the first holder 230 with the transforming mechanism 321, and attracts the lower wafer W2 again, but the present disclosure is not limited thereto. The transforming mechanism 321 may transform the first holder 230 in the state where the first holder 230 attracts the lower wafer W2.

Specifically, the controller 71 may control the first holder 230 to hold the lower wafer W2. Then, the controller 71 may control the outer attraction structure 301 and the inner attraction structure 302 to attract the lower wafer W2. Subsequently, the controller 71 may acquire the height information of the peripheral portion of the lower wafer W2 based on the attraction surface 300 from the displacement sensor 340. Thereafter, the controller 71 may control the transforming mechanism 321 to transform the outer attraction structure 301 based on the acquired information. That is, in the process S204 shown in FIG. 12, the controller 71 may perform only the control of the transforming mechanism 321 without performing the processing of releasing and re-attracting the lower wafer W2.

As a result, compared to the case where the lower wafer W2 is released and attracted again, the time required for the bonding processing can be reduced.

The embodiments disclosed herein are illustrative in all aspects and do not limit the present disclosure. In fact, the above embodiments can be embodied in various forms. Further, the above-described embodiments may be omitted, substituted, or changed in various forms without departing from the scope and spirit of the appended claims.

The present disclosure may also take the following configurations.

(1) A bonding apparatus, including:
a first holder configured to hold a first substrate from below;
a second holder disposed above the first holder and configured to hold a second substrate from above;
a pushing member provided in the second holder and configured to push down a central portion of the second substrate; and
a controller,
wherein the first holder includes:
an outer attraction structure configured to attract a peripheral portion of the first substrate;
an inner attraction structure configured to attract a portion of the first substrate inside the peripheral portion;
a transforming mechanism configured to transform the outer attraction structure relative to the inner attraction structure, and
the controller acquires information of a height of the peripheral portion of the first substrate from a reference surface and controls the transforming mechanism based on the acquired information.

(2) The bonding apparatus of (1),
wherein when the height of the peripheral portion of the first substrate from the reference surface is in a threshold range including a target height, the controller controls the transforming mechanism based on an amount of deviation from the target height.

(3) The bonding apparatus of (2),
wherein the transforming mechanism is provided with a transformation space in the first holder located at the outer attraction structure, and
when the height of the peripheral portion of the first substrate from the reference surface is out of the threshold range including the target height, the controller controls the transforming mechanism to supply a fluid to the transformation space to expand the outer attraction structure with respect to the inner attraction structure

(4) The bonding apparatus of (1) to (3), further including:
a measurement apparatus configured to measure the height of the peripheral portion of the first substrate based on an attraction surface of the outer attraction structure,
wherein the controller controls the transforming mechanism based on information acquired from the measurement apparatus.

(5) The bonding apparatus of (1) to (4),
wherein an outer edge of the first substrate is located at a widthwise intermediate portion of the outer attraction structure.

(6) The bonding apparatus of (4),
wherein the controller controls the first holder to hold the first substrate, acquires the information of the height of the peripheral portion of the first substrate based on the attraction surface of the outer attraction structure from the measurement apparatus, controls the transforming mechanism to transform the outer attraction structure based on the acquired information, and controls the outer attraction structure and the inner attraction structure to attract the first substrate.

(7) The bonding apparatus of (4),
wherein the controller controls the first holder to hold the first substrate, controls the outer attraction structure and the inner attraction structure to attract the first substrate, acquires the information of the height of the peripheral portion of the first substrate based on the attraction surface of the outer attraction structure from the measurement apparatus, and controls the transforming mechanism to transform the outer attraction structure based on the acquired information.

(8) A bonding method, including:
holding a first substrate from below with a first holder configured to hold the first substrate from below;
holding a second substrate from above with a second holder disposed above the first holder and configured to hold the second substrate from above;
acquiring information of a height of a peripheral portion of the first substrate from a reference surface;
transforming an outer attraction structure configured to attract the peripheral portion of the first substrate with a transforming mechanism configured to transform the outer attraction structure relative to an inner attraction structure configured to attract a portion of the first substrate inside the peripheral portion based on the acquired information;
attracting the first substrate with the outer attraction structure and the inner attraction structure; and
pushing down a central portion of the second substrate held by the second holder with a pushing member provided in the second holder and configured to push down the central portion of the second substrate.

According to the exemplary embodiment, it is possible to appropriately adjust the height of the peripheral portion of the substrate.

From the foregoing, it will be appreciated that various exemplary embodiments of the present disclosure have been described herein for purposes of illustration and various changes can be made without departing from the scope and spirit of the present disclosure. Accordingly, various exemplary embodiments described herein are not intended to be limiting, and the true scope and spirit are indicated by the following claims.

We claim:

1. A bonding apparatus, comprising:
a first holder configured to hold a first substrate from below the first substrate;
a second holder disposed above the first holder and configured to hold a second substrate from above the second substrate, the second holder including a pushing member configured to push down a central portion of the second substrate; and
a controller having a processor and a memory with a computer readable program stored therein,
wherein the first holder includes:
an outer attraction structure configured to attract a peripheral portion of the first substrate;
an inner attraction structure configured to attract a portion of the first substrate inside the peripheral portion; and
a transforming mechanism configured to transform the outer attraction structure relative to the inner attraction structure, and
the controller is configured to:
acquire information of a height of the peripheral portion of the first substrate from a reference surface, and
control the transforming mechanism based on the acquired information.

2. The bonding apparatus of claim 1,
wherein when the height of the peripheral portion of the first substrate from the reference surface is in a threshold range including a target height, the controller is configured to control the transforming mechanism based on an amount of deviation from the target height.

3. The bonding apparatus of claim 2,
wherein the transforming mechanism is provided with a transformation space in the first holder located at the outer attraction structure, and
when the height of the peripheral portion of the first substrate from the reference surface is outside of the threshold range, the controller is configured to control the transforming mechanism to supply a fluid to the transformation space to expand the outer attraction structure with respect to the inner attraction structure.

4. The bonding apparatus of claim 1, further comprising:
a measurement apparatus configured to measure the height of the peripheral portion of the first substrate based on an attraction surface of the outer attraction structure,
wherein the controller is configured to control the transforming mechanism based on information acquired from the measurement apparatus.

5. The bonding apparatus of claim 1,
wherein an outer edge of the first substrate is located at a widthwise intermediate portion of the outer attraction structure.

6. The bonding apparatus of claim 4,
wherein the controller is configured to:
control the first holder to hold the first substrate,
acquire the information of the height of the peripheral portion of the first substrate based on the attraction surface of the outer attraction structure from the measurement apparatus,
control the transforming mechanism to transform the outer attraction structure based on the acquired information, and
control the outer attraction structure and the inner attraction structure to attract the first substrate.

7. The bonding apparatus of claim 4,
wherein the controller is configured to:
control the first holder to hold the first substrate,
control the outer attraction structure and the inner attraction structure to attract the first substrate,
acquire the information of the height of the peripheral portion of the first substrate based on the attraction surface of the outer attraction structure from the measurement apparatus, and
control the transforming mechanism to transform the outer attraction structure based on the acquired information.

8. A bonding method, comprising:
holding, by a first holder, a first substrate from below the first substrate, wherein the first holder includes:
an outer attraction structure;
an inner attraction structure; and
a transforming mechanism;
holding, by a second holder, a second substrate from above the second substrate;
acquiring information of a height of a peripheral portion of the first substrate from a reference surface;
transforming, by the transforming mechanism, the outer attraction structure relative to an inner attraction structure,
attracting, by the outer attraction structure, the peripheral portion of the first substrate,
attracting, by the inner attraction structure, a portion of the first substrate inside the peripheral portion based on the acquired information; and
pushing down, by a pushing member provided in the second holder, a central portion of the second substrate held by the second holder.

9. The bonding method of claim 8, further comprising:
when the height of the peripheral portion of the first substrate from the reference surface is in a threshold range including a target height, controlling, by a controller, the transforming mechanism based on an amount of deviation from the target height.

10. The bonding method of claim 9,
wherein the transforming mechanism is provided with a transformation space in the first holder located at the outer attraction structure, and
the method further comprises, when the height of the peripheral portion of the first substrate from the reference surface is outside of the threshold range, controlling, by the controller, the transforming mechanism to supply a fluid to the transformation space to expand the outer attraction structure with respect to the inner attraction structure.

11. The bonding method of claim 8, further comprising:
measuring, by a measurement apparatus, the height of the peripheral portion of the first substrate based on an attraction surface of the outer attraction structure; and
controlling, by a controller, the transforming mechanism based on information acquired from the measurement apparatus.

12. The bonding method of claim 8,
wherein an outer edge of the first substrate is located at a widthwise intermediate portion of the outer attraction structure.

13. The bonding method of claim 11, further comprising:
controlling, by the controller, the first holder to hold the first substrate;
acquiring, by the controller, the information of the height of the peripheral portion of the first substrate based on the attraction surface of the outer attraction structure from the measurement apparatus;
controlling, by the controller, the transforming mechanism to transform the outer attraction structure based on the acquired information; and
controlling, by the controller, the outer attraction structure and the inner attraction structure to attract the first substrate.

14. The bonding method of claim 11, further comprising:
controlling, by the controller, the outer attraction structure and the inner attraction structure to attract the first substrate;
acquiring, by the controller, the information of the height of the peripheral portion of the first substrate based on the attraction surface of the outer attraction structure from the measurement apparatus; and
controlling, by the controller, the transforming mechanism to transform the outer attraction structure based on the acquired information.

15. A bonding apparatus, comprising:
a first holder configured to hold a first substrate from below the first substrate, the first holder including:
an outer attraction structure configured to attract a peripheral portion of the first substrate;
an inner attraction structure configured to attract a portion of the first substrate inside the peripheral portion; and
a transforming mechanism configured to transform the outer attraction structure relative to the inner attraction structure;
a second holder facing the first holder and configured to hold a second substrate from above the second substrate, the second holder including:
a vacuum pump; and
a plurality of holding pins connected to the vacuum pump, the plurality of holding pins being configured to vacuum-attract the second substrate by an operation of the vacuum pump; and
a controller having a processor and a memory with a computer readable program stored therein that upon execution of the computer readable program by the processor causes the controller to:
acquire information of a height of the peripheral portion of the first substrate from a reference surface, and
control the transforming mechanism based on the acquired information to correct the height of the peripheral portion of the first substrate.

16. The bonding apparatus of claim 15,
wherein when the height of the peripheral portion of the first substrate from the reference surface is in a threshold range including a target height, the controller is configured to control the transforming mechanism based on an amount of deviation from the target height.

17. The bonding apparatus of claim 16,
wherein the transforming mechanism is provided with a transformation space in the first holder located at the outer attraction structure, and
when the height of the peripheral portion of the first substrate from the reference surface is outside of the threshold range, the controller is configured to control the transforming mechanism to supply a fluid to the transformation space to expand the outer attraction structure with respect to the inner attraction structure.

18. The bonding apparatus of claim 15, further comprising:
a measurement apparatus configured to measure the height of the peripheral portion of the first substrate based on an attraction surface of the outer attraction structure,
wherein the controller is configured to control the transforming mechanism based on information acquired from the measurement apparatus.

19. The bonding apparatus of claim 18,
wherein the controller is configured to:
control the first holder to hold the first substrate,
acquire the information of the height of the peripheral portion of the first substrate based on the attraction surface of the outer attraction structure from the measurement apparatus,
control the transforming mechanism to transform the outer attraction structure based on the acquired information, and
control the outer attraction structure and the inner attraction structure to attract the first substrate.

20. The bonding apparatus of claim 18,
wherein the controller is configured to:
control the outer attraction structure and the inner attraction structure to attract the first substrate,
acquire the information of the height of the peripheral portion of the first substrate based on the attraction surface of the outer attraction structure from the measurement apparatus, and
control the transforming mechanism to transform the outer attraction structure based on the acquired information.
